(19) United States
(12) Patent Application Publication
(10) Pub. No.: US 2025/0096747 A1
(43) Pub. Date: Mar. 20, 2025

(54) MILLIMETER-WAVE (MMW) LOW NOISE ACTIVE PHASE SHIFTER

(71) Applicant: QUALCOMM INCORPORATED, SAN DIEGO, CA (US)

(72) Inventors: Laya MOHAMMADI, San Diego, CA (US); Chirag Dipak PATEL, San Diego, CA (US); Chuan WANG, San Diego, CA (US); Bhushan Shanti ASURI, San Diego, CA (US)

(21) Appl. No.: 18/470,039

(22) Filed: Sep. 19, 2023

(51) Int. Cl. H03F 3/195; H03F 1/56; H04B 1/40

(52) U.S. Cl. CPC H03F 3/195; H03F 1/56; H04B 1/40; H03F 2200/222; H03F 2200/451

(57) ABSTRACT

A phase shifter having an input matching network, a vector modulator connected to the input matching network, the vector modulator configured to alter an amplitude of signals provided by the input matching network, bias networks coupled to outputs of the vector modulator, and a combining circuit connected to the outputs of the vector modulator, the combining circuit configured to generate a first phase (θ1) signal from the outputs of the vector modulator.

### FIELD

The present disclosure relates generally to electronics, and more specifically to phase shifters in transceivers.

### BACKGROUND

Wireless communication devices and technologies are becoming ever more prevalent, as are communication devices that operate at millimeter-wave (mmW) and sub-terahertz (subTHz) frequencies. Wireless communication devices generally transmit and/or receive communication signals. In a radio frequency (RF) transceiver, a communication signal is typically amplified and transmitted by a transmit section and a received communication signal is amplified and processed by a receive section. A transceiver for communication in 5G and 6G applications may communicate using millimeter wave (mmW) frequency signals and/or sub-THz frequencies and may use what is referred to as a zero intermediate frequency (ZIF) architecture or a low-IF architecture.

Transceivers used in 5G communication systems may use what is referred to as beamforming to increase system capacity. Beamforming generally uses individual transmit and receive elements where a phase shifter alters the phase of the signal. Typically, many such elements and phase shifters are implemented in such a system. Typically, each TX/RX element uses two phase shifters, one for transmit and one for receive.

An active phase shifter is typically used in a transmit application because it provides good signal gain and generally consumes small area. An active phase shifter may use some passive circuitry. For example, a passive circuit may generate the in-phase (I) and quadrature (Q) signals and a vector modulator (VM), which is an active circuit, provides the desire phase shift to the I and Q signals. However, there are challenges when combining a passive IQ input circuit with the vector modulator. For example, a passive IQ circuit may generate noise and may create imbalances in the I and Q signals. These imbalances should be corrected before the I and Q signals are applied to the vector modulator for phase shifting. Such circuitry consumes significant power and may generate significant system noise so as to make it difficult to implement in a receive chain.

### SUMMARY

Various implementations of systems, methods and devices within the scope of the appended claims each have several aspects, no single one of which is solely responsible for the desirable attributes described herein. Without limiting the scope of the appended claims, some prominent features are described herein.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

One aspect of the disclosure provides a phase shifter having an input matching network, a vector modulator connected to the input matching network, the vector modulator configured to alter an amplitude of signals provided by the input matching network, bias networks coupled to outputs of the vector modulator, and a combining circuit connected to the outputs of the vector modulator, the combining circuit configured to generate a first phase (θ1) signal from the outputs of the vector modulator.

Another aspect of the disclosure provides a method for phase shifting including dividing an input signal into a first portion and a second portion and adjusting an amplitude of the first and second portions, biasing the amplitude-adjusted first portion and the amplitude-adjusted second portion; and passively combining the amplitude-adjusted first and second portions to generate a first phase (θ1) signal.

Another aspect of the disclosure provides a device including means for dividing an input signal into a first portion and a second portion and actively adjusting an amplitude of the first and second portions, means for biasing the amplitude-adjusted first portion and the amplitude-adjusted second portion, and means for passively combining the amplitude-adjusted first portion and the amplitude-adjusted second portion using a passive combiner to generate a first phase (θ1) signal.

Another aspect of the disclosure provides a phase shifter including an input matching network coupled to an input of the phase shifter, a variable gain amplifier, wherein an output of the input matching network is coupled to a gate of an amplification transistor in the variable gain amplifier, and a quadrature all pass filter (QAF) coupled to an output of the variable gain amplifier and to an output of the phase shifter.

### BRIEF DESCRIPTION OF THE DRAWINGS

In the figures, like reference numerals refer to like parts throughout the various views unless otherwise indicated. For reference numerals with letter character designations such as “102a” or “102b”, the letter character designations may differentiate two like parts or elements present in the same figure. Letter character designations for reference numerals may be omitted when it is intended that a reference numeral encompass all parts having the same reference numeral in all figures.

FIG. 1 is a diagram showing a wireless device communicating with a wireless communication system.

FIG. 2A is a block diagram showing a wireless device in which exemplary techniques of the present disclosure may be implemented.

FIG. 2B is a block diagram showing a wireless device in which exemplary techniques of the present disclosure may be implemented.

FIG. 2C is a block diagram showing a wireless device in which exemplary techniques of the present disclosure may be implemented.

FIG. 3 is a diagram showing a portion of the circuitry on an integrated circuit (IC).

FIG. 4 is a schematic diagram of a phase shifter of FIG. 3.

FIG. 5 is a graphical illustration of the operation of the combining circuit of FIG. 4.

FIG. 6 is a flow chart describing an example of the operation of a method for phase shifting.

FIG. 7 is a functional block diagram of an apparatus for phase shifting.

### DETAILED DESCRIPTION

The word “exemplary” is used herein to mean “serving as an example, instance, or illustration.” Any aspect described herein as “exemplary” is not necessarily to be construed as preferred or advantageous over other aspects.

In an exemplary embodiment, a phase shifter may include a vector modulator to vary signal amplitude followed by a quadrature all pass filter (QAF) to generate the I and Q signals,

In an exemplary embodiment, a QAF following a vector modulator in a phase shift circuit minimizes a need for a matching network between the vector modulator and the QAF.

In an exemplary embodiment, a phase shift circuit having a QAF following a vector modulator is efficient in area consumption.

In an exemplary embodiment, a phase shift circuit having a QAF following a vector modulator provides a low noise figure (NF) and may be implemented in a receive chain.

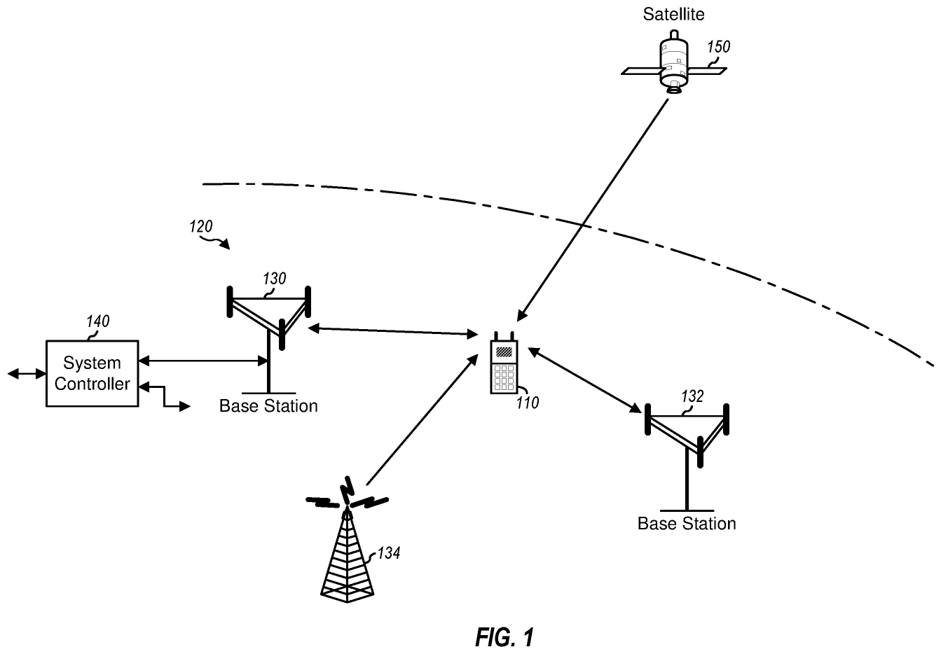

FIG. 1 is a diagram showing a wireless device 110 communicating with a wireless communication system 120. The wireless communication system 120 may be a Long Term Evolution (LTE) system, a Code Division Multiple Access (CDMA) system, a Global System for Mobile Communications (GSM) system, a wireless local area network (WLAN) system, a 5G NR (new radio) system, or some other wireless system. A CDMA system may implement Wideband CDMA (WCDMA), CDMA 1X, Evolution-Data Optimized (EVDO), Time Division Synchronous CDMA (TD-SCDMA), or some other version of CDMA. For simplicity, FIG. 1 shows wireless communication system 120 including two base stations 130 and 132 and one system controller 140. In general, a wireless communication system may include any number of base stations and any set of network entities.

The wireless device 110 may also be referred to as a user equipment (UE), a mobile station, a terminal, an access terminal, a subscriber unit, a station, etc. Wireless device 110 may be a cellular phone, a smartphone, a tablet, a wireless modem, a personal digital assistant (PDA), a handheld device, a laptop computer, a smartbook, a netbook, a tablet, a cordless phone, a medical device, an automobile, a device configured to connect to one or more other devices (for example through the internet of things), a customer premises equipment (CPE), a wireless local loop (WLL) station, a Bluetooth device, etc. Wireless device 110 may communicate with wireless communication system 120. Wireless device 110 may also receive signals from broadcast stations (e.g., a broadcast station 134) and/or communicate with satellites (e.g., a satellite 150 in one or more global navigation satellite systems (GNSS)), etc.). Wireless device 110 may support one or more radio technologies for wireless communication such as LTE, WCDMA, CDMA 1X, EVDO, TD-SCDMA, GSM, 802.11, 802.15, 5G, Sub6 5G, 6G, UWB, etc.

Wireless device 110 may be able to operate in a variety of communication bands including, for example, those communication bands used by LTE, WiFi, 5G or other communication bands, over a wide range of frequencies. Wireless device 110 may also be capable of communicating directly with other wireless devices without communicating through a network.

Wireless device 110 may support carrier aggregation, for example as described in one or more LTE or 5G standards. In some embodiments, a single stream of data is transmitted over multiple carriers using carrier aggregation, for example as opposed to separate carriers being used for respective data streams. In general, carrier aggregation (CA) may be categorized into two types-intra-band CA and inter-band CA. Intra-band CA refers to operation on multiple carriers within the same band. Inter-band CA refers to operation on multiple carriers in different bands.

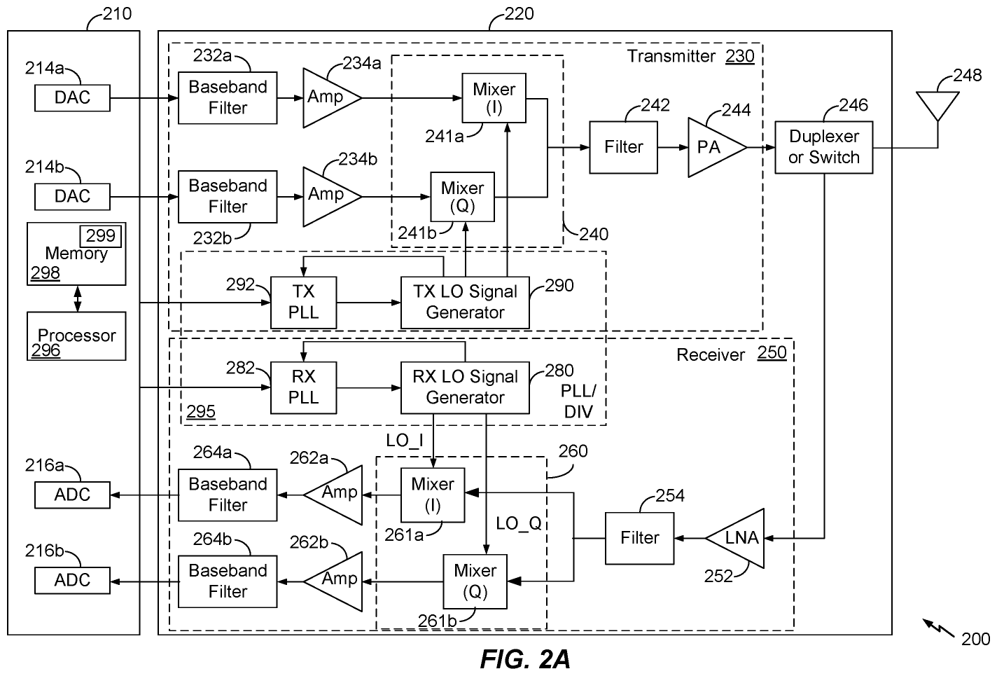

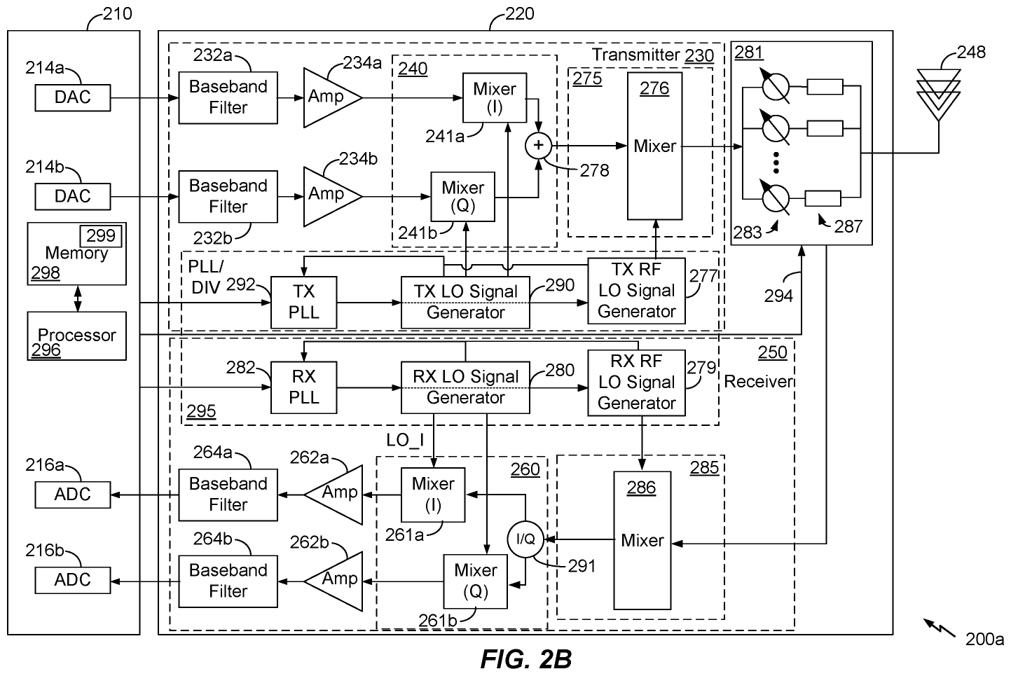

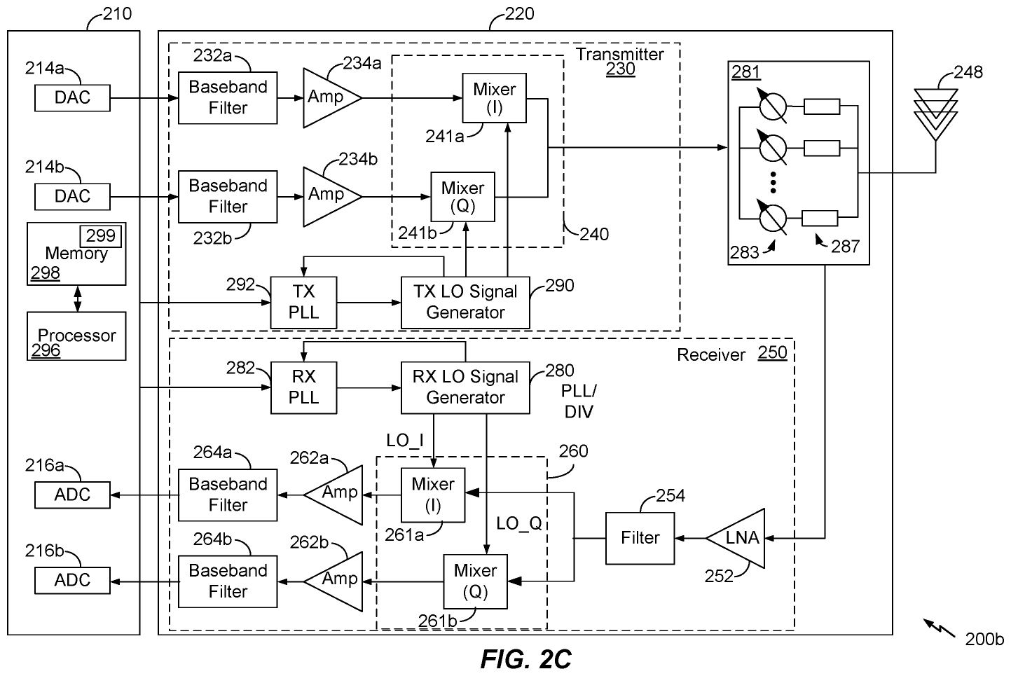

FIG. 2A is a block diagram showing a wireless device 200 in which the exemplary techniques of the present disclosure may be implemented. The wireless device 200 may, for example, be an embodiment of the wireless device 110 illustrated in FIG. 1.

FIG. 2A shows an example of a transceiver 220 having a transmitter 230 and a receiver 250. In general, the conditioning of the signals in the transmitter 230 and the receiver 250 may be performed by one or more stages of amplifier, filter, upconverter, downconverter, etc. These circuit blocks may be arranged differently from the configuration shown in FIG. 2A. Furthermore, other circuit blocks not shown in FIG. 2A may also be used to condition the signals in the transmitter 230 and receiver 250, for example phase shifters as discussed further below. Unless otherwise noted, any signal in FIG. 2A, or any other figure in the drawings, may be either single-ended or differential. Some circuit blocks in FIG. 2A may also be omitted.

In the example shown in FIG. 2A, wireless device 200 generally comprises the transceiver 220 and a data processor 210. The data processor 210 may include a processor 296 operatively coupled to a memory 298. The memory 298 may be configured to store data and program codes shown generally using reference numeral 299, and may generally comprise analog and/or digital processing components. The transceiver 220 includes a transmitter 230 and a receiver 250 that support bi-directional communication. In general, wireless device 200 may include any number of transmitters and/or receivers for any number of communication systems and frequency bands. All or a portion of the transceiver 220 may be implemented on one or more analog integrated circuits (ICs), RF ICs (RFICs), mixed-signal ICs, etc.

A transmitter or a receiver may be implemented with a super-heterodyne architecture or a direct-conversion architecture. In the super-heterodyne architecture, a signal is frequency-converted between radio frequency (RF) and baseband in multiple stages, e.g., from RF to an intermediate frequency (IF) in one stage, and then from IF to baseband in another stage for a receiver. In the direct-conversion architecture, a signal is frequency converted between RF and baseband in one stage. The super-heterodyne and direct-conversion architectures may use different circuit blocks and/or have different requirements. In the example shown in FIG. 2A, transmitter 230 and receiver 250 are implemented with the direct-conversion architecture.

In the transmit path, the data processor 210 processes data to be transmitted and provides in-phase (I) and quadrature (Q) analog output signals to the transmitter 230. In an exemplary embodiment, the data processor 210 includes digital-to-analog-converters (DAC's) 214a and 214b for converting digital signals generated by the data processor 210 into the I and Q analog output signals, e.g., I and Q output currents, for further processing. In other embodiments, the DACs 214a and 214b are included in the transceiver 220 and the data processor 210 provides data (e.g., for I and Q) to the transceiver 220 digitally.

Within the transmitter 230, lowpass filters 232a and 232b filter the I and Q analog transmit signals, respectively, to remove undesired images caused by the prior digital-to-analog conversion. Amplifiers (Amp) 234a and 234b amplify the signals from lowpass filters 232a and 232b, respectively, and provide I and Q baseband signals. An upconverter 240 having upconversion mixers 241a and 241b upconverts the I and Q baseband signals with I and Q transmit (TX) local oscillator (LO) signals from a TX LO signal generator 290 and provides an upconverted signal. A filter 242 filters the upconverted signal to remove undesired images caused by the frequency upconversion as well as noise in a receive frequency band. A power amplifier (PA) 244 amplifies the signal from filter 242 to obtain the desired output power level and provides a transmit RF signal. The transmit RF signal is routed through a duplexer or switch 246 and transmitted via an antenna 248, or alternatively it can be sent to a separate transmit antenna different from a separate receive antenna. While examples discussed herein utilize I and Q signals, those of skill in the art will understand that components of the transceiver may be configured to utilize polar modulation.

In the receive path, antenna 248 receives communication signals and provides a received RF signal, which can be routed through duplexer or switch 246 and provided to a low noise amplifier (LNA) 252. The duplexer 246 is designed to operate with a specific RX-to-TX duplexer frequency separation, such that RX signals are isolated from TX signals. Alternatively, there may be a separate transmit antenna and separate receive antenna as mentioned above, in which case RX-to-TX isolation can be achieved through the limited coupling between the two antennas. In the case of separate RX and TX antennas, the RX antenna can be coupled directly to LNA 252. The received RF signal is amplified by LNA 252 and filtered by a filter 254 to obtain a desired RF input signal. Downconversion mixers 261a and 261b in a downconverter 260 mix the output of filter 254 with I and Q receive (RX) LO signals (i.e., LO_I and LO_Q) from an RX LO signal generator 280 to generate I and Q baseband signals. The I and Q baseband signals are amplified by amplifiers 262a and 262b and further filtered by lowpass filters 264a and 264b to obtain I and Q analog input signals, which are provided to data processor 210. In the exemplary embodiment shown, the data processor 210 includes analog-to-digital-converters (ADC's) 216a and 216b for converting the analog input signals into digital signals to be further processed by the data processor 210. In some embodiments, the ADCs 216a and 216b are included in the transceiver 220 and provide data to the data processor 210 digitally.

In FIG. 2A, TX LO signal generator 290 generates the I and Q TX LO signals used for frequency upconversion, while RX LO signal generator 280 generates the I and Q RX LO signals used for frequency downconversion. Each LO signal is a periodic signal with a particular fundamental frequency. A phase locked loop (PLL) 292 receives timing information from data processor 210 and generates a control signal used to adjust the frequency and/or phase of the TX LO signals from LO signal generator 290. Similarly, a PLL 282 receives timing information from data processor 210 and generates a control signal used to adjust the frequency and/or phase of the RX LO signals from LO signal generator 280.

In an exemplary embodiment, the RX PLL 282, the TX PLL 292, the RX LO signal generator 280, and the TX LO signal generator 290 may alternatively be combined into a single LO generator circuit 295, which may include common or shared LO signal generator circuitry to provide the TX LO signals and the RX LO signals. Alternatively, separate LO generator circuits may be used to generate the TX LO signals and the RX LO signals.

Wireless device 200 may support CA and may (i) receive multiple downlink signals transmitted by one or more cells on multiple downlink carriers at different frequencies and/or (ii) transmit multiple uplink signals to one or more cells on multiple uplink carriers. Those of skill in the art will understand, however, that aspects described herein may be implemented in systems, devices, and/or architectures that do not support carrier aggregation.

Certain components of the transceiver 220 are functionally illustrated in FIG. 2A, and the configuration illustrated therein may or may not be representative of a physical device configuration in certain implementations. For example, as described above, transceiver 220 may be implemented in various integrated circuits (ICs), RF ICs (RFICs), mixed-signal ICs, etc. In some embodiments, the transceiver 220 is implemented on a substrate or board such as a printed circuit board (PCB) having various modules, chips, and/or components. For example, the power amplifier 244, the filter 242, and the duplexer 246 may be implemented in separate modules or as discrete components, while the remaining components illustrated in the transceiver 220 may be implemented in a single transceiver chip.

The power amplifier 244 may comprise one or more stages comprising, for example, driver stages, power amplifier stages, or other components, that can be configured to amplify a communication signal on one or more frequencies, in one or more frequency bands, and at one or more power levels. Depending on various factors, the power amplifier 244 can be configured to operate using one or more driver stages, one or more power amplifier stages, one or more impedance matching networks, and can be configured to provide good linearity, efficiency, or a combination of good linearity and efficiency.

In an exemplary embodiment in a super-heterodyne architecture, the filter 242, PA 244, LNA 252 and filter 254 may be implemented separately from other components in the transmitter 230 and receiver 250, and may be implemented on a millimeter wave integrated circuit. An example super-heterodyne architecture is illustrated in FIG. 2B.

FIG. 2B is a block diagram showing a wireless device in which the exemplary techniques of the present disclosure may be implemented. Certain components, for example which may be indicated by identical reference numerals, of the wireless device 200a in FIG. 2B may be configured similarly to those in the wireless device 200 shown in FIG. 2A and the description of identically numbered items in FIG. 2B will not be repeated.

The wireless device 200a is an example of a heterodyne (or superheterodyne) architecture in which the upconverter 240 and the downconverter 260 are configured to process a communication signal between baseband and an intermediate frequency (IF). For example, the upconverter 240 may be configured to provide an IF signal to an upconverter 275. In an exemplary embodiment, the upconverter 275 may comprise upconversion mixer 276. The summing function 278 of upconverter 240 combines the I and the Q outputs and provides a combined signal to the mixer 276. The combined signal may be single ended or differential. The mixer 276 is configured to receive the IF signal from the upconverter 240 and TX RF LO signals from a TX RF LO signal generator 277, and provide an upconverted RF signal to phase shift circuitry 281. While PLL 292 is illustrated in FIG. 2B as being shared by the signal generators 290, 277, a respective PLL for each signal generator may be implemented.

In an exemplary embodiment, components in the phase shift circuitry 281 may comprise one or more adjustable or variable phased array elements, and may receive one or more control signals from the data processor 210 over connection 294 and operate the adjustable or variable phased array elements based on the received control signals.

In an exemplary embodiment, the phase shift circuitry 281 comprises phase shifters 283 and phased array elements 287. Although three phase shifters 283 and three phased array elements 287 are shown for ease of illustration, the phase shift circuitry 281 may comprise more or fewer phase shifters 283 and phased array elements 287.

Each phase shifter 283 may be configured to receive the RF transmit signal from the upconverter 275, alter the phase by an amount, and provide the RF signal to a respective phased array element 287. Each phased array element 287 may comprise transmit and receive circuitry including one or more filters, amplifiers, driver amplifiers, and power amplifiers. In some embodiments, the phase shifters 283 may be incorporated within respective phased array elements 287.

The output of the phase shift circuitry 281 is provided to an antenna array 248. In an exemplary embodiment, the antenna array 248 comprises a number of antennas that typically correspond to the number of phase shifters 283 and phased array elements 287, for example such that each antenna element is coupled to a respective phased array element 287. In an exemplary embodiment, the phase shift circuitry 281 and the antenna array 248 may be referred to as a phased array.

In a receive direction, an output of the phase shift circuitry 281 is provided to a downconverter 285. In an exemplary embodiment, the downconverter 285 may comprise a downconversion mixer 286. In an exemplary embodiment, the mixer 286 downconverts the receive RF signal provided by the phase shift circuitry 281 to an IF signal according to RX RF LO signals provided by an RX RF LO signal generator 279. The I/Q generation function 291 of downconverter 260 receives the IF signal from the mixer 286 and generates I and Q signals in downconverter 260, which downconverts the IF signals to baseband, as described above. While PLL 282 is illustrated in FIG. 2B as being shared by the signal generators 280, 279, a respective PLL for each signal generator may be implemented.

In some embodiments, the upconverter 275, downconverter 285, and the phase shift circuitry 281 are implemented on a common IC. In some embodiments, the summing function 278 and the I/Q generation function 291 are implemented separate from the mixers 276 and 286 such that the mixers 276, 286 and the phase shift circuitry 281 are implemented on the common IC, but the summing function 278 and I/Q generation function 291 are not (e.g., the summing function 278 and I/Q generation function 291 are implemented in another IC coupled to the IC having the mixers 276, 286). In some embodiments, the LO signal generators 277, 279 are included in the common IC. In some embodiments in which phase shift circuitry is implemented on a common IC with 276, 286, 277, 278, 279, and/or 291, the common IC and the antenna array 248 are included in (e.g., packaged together in) a module, which may be coupled to other components of the transceiver 220 via a connector. In some embodiments, the phase shift circuitry 281, for example, a chip on which the phase shift circuitry 281 is implemented, is coupled to the antenna array 248 by an interconnect. For example, components of the antenna array 248 may be implemented on a substrate and coupled to an integrated circuit implementing the phase shift circuitry 281 via a flexible printed circuit or the chip may be mounted on the substrate.

In some embodiments, both the architecture illustrated in FIG. 2A and the architecture illustrated in FIG. 2B are implemented in the same device. For example, a wireless device 110 or 200 may be configured to communicate with signals having a frequency below about 7 GHz (e.g., the FR1 frequency band) using the architecture illustrated in FIG. 2A and to communicate with signals having a frequency above about 24 GHz using the architecture illustrated in FIG. 2B. In devices in which both architectures are implemented, one or more components of FIGS. 2A and 2B that are identically numbered may be shared between the two architectures. For example, both signals that have been downconverted directly to baseband from RF and signals that have been downconverted from RF to baseband via an IF stage may be filtered by the same baseband filter 264. In other embodiments, a first version of the filter 264 is included in the portion of the device which implements the architecture of FIG. 2A and a second version of the filter 264 is included in the portion of the device which implements the architecture of FIG. 2B.

FIG. 2C is a block diagram showing a wireless device in which exemplary techniques of the present disclosure may be implemented. Certain components, for example which may be indicated by identical reference numerals, of the wireless device 200b in FIG. 2C may be configured similarly to those in the wireless device 200 shown in FIG. 2A and/or the wireless device 200a shown in FIG. 2B and the description of identically numbered items in FIG. 2C will not be repeated.

The wireless device 200b in FIG. 2C incorporates the phase shift circuitry 281 (of FIG. 2B) in a direct conversion architecture, where communication signals are upconverted and downconverted between baseband and RF without the use of intermediate frequency (IF) signal conversion. Such an architecture may be configured as a low IF (LIF), or a zero IF (ZIF) architecture. For example, the LO signals in the architecture of FIG. 2C may comprise signals at frequencies of tens of GHz. In other examples, the LO signals may be a single digit or low double digit GHz frequency (for example, when the wireless device 200b is configured for use with signals in an FR3 band) or hundreds of GHz (for example, when the wireless device 200b is configured for use with signals in a sub-THz band).

In some embodiments, the upconverter 240, downconverter 260, and the phase shift circuitry 281 are implemented on a common IC. In some embodiments, the LO signal generators 280, 290 are included in the common IC. In some embodiments, the common IC and the antenna array 248 are included in (e.g., packaged together in) a module, which may be coupled to other components of the transceiver 220 via a connector. In some embodiments, the phase shift circuitry 281, for example, a chip on which the phase shift circuitry 281 is implemented, is coupled to the antenna array 248 by an interconnect or both are mounted to a substrate. For example, components of the antenna array 248 may be implemented on a substrate and coupled to an integrated circuit implementing the phase shift circuitry 281 via a flexible printed circuit or the integrated circuit may be mounted to an opposite side of the substrate. In some embodiments, multiple iterations of the upconverter 240 and downconverter 260 may be implemented to process multiple signals on different frequency bands.

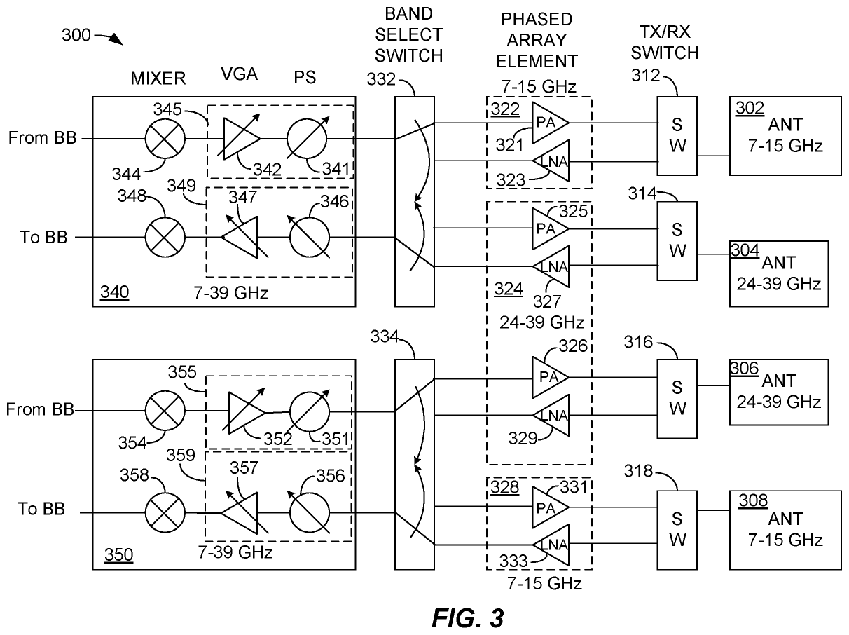

FIG. 3 is a diagram showing a portion of the circuitry 300 including a phase shifter that may be implemented on an integrated circuit such as a millimeter wave integrated circuit (mmW-IC) which also supports frequencies in FR3. As discussed above, however, the circuitry 300 may be configured to omit support for mmW frequencies or omit support for FR3 frequencies, or may additionally or alternatively be configured for use with other frequencies (e.g., sub-THz).

In an exemplary embodiment, some or all of the circuitry 300 may be fully or partially implemented on a mmW-IC or on one or more mmW-ICs.

In an exemplary embodiment, the circuitry 300 may include antennas 302, 304, 306 and 308. The antennas 302, 304, 306 and 308 may be part of the antenna array 248 of FIG. 2C, and may be configured to cover different frequency ranges. For example, the antenna 302 and the antenna 308 may be configured to operate on the 7-15 GHz band (e.g., in FR3) and the antennas 304 and 306 may be configured to operate on the 24-39 GHz band (e.g., mmW or FR2).

In an exemplary embodiment, the antenna 302 may be connected to a TX/RX switch 312, the antenna 304 may be connected to a TX/RX switch 314, antenna 306 may be connected to a TX/RX switch 316, and the antenna 308 may be connected to a TX/RX switch 318. The TX/RX switch 312 may be connected to a phased array element 322, the TX/RX switches 314 and 316 may be connected to a phased array element 324, and the TX/RX switch 318 may be connected to a phased array element 328. In an exemplary embodiment, the phased array element 322 and the phased array element 328 may be configured to operate on the 7-15 GHz band (λ1) (or in a range of 7-24 GHz) and the phased array element 324 may be configured to operate on the 24-39 GHz band (λ2). In some examples, another component besides a TX/RX switch is used to separate TX and RX signals. For example, a duplexer or electromagnetic (EM) elements may be used.

In an exemplary embodiment, the phased array element 322 may comprise a power amplifier (PA) 321 and a low noise amplifier (LNA) 323. Although shown as single elements, the power amplifier 321 and the LNA 323 may comprise more than one amplification stage.

In an exemplary embodiment, the phased array element 324 may comprise a power amplifier 325 and a power amplifier 326; and may comprise an LNA 323 and an LNA 329. Although shown as single elements, the power amplifiers 325 and 326 and the LNAs 327 and 329 may comprise more than one amplification stage.

In an exemplary embodiment, the phased array element 328 may comprise a power amplifier 331 and an LNA 333. Although shown as single element, the power amplifier 331 and the LNA 333 may comprise more than one amplification stage.

In an exemplary embodiment, a band select switch 332 may be connected to the phased array element 322 and the phased array element 324; and a band select switch 334 may be connected to the phased array element 324 and the phased array element 328.

Although shown as part of the circuitry 300, in some embodiments, the phased array elements 322, 324 and 328 may be located on a separate radio frequency (RF) module. Further, the antennas 302, 304, 306 and 308 are not necessarily included on the mmW-IC. The antennas 302, 304, 306 and 308 may be part of a separate substrate, and may be packaged into a module with the mmW-IC or spaced from the mmW-IC.

Frequency conversion components 340 may include an upconversion mixer 344, a beamformer 345, a downconversion mixer 348 and a beamformer 349. In an exemplary embodiment, the beamformer 345 may include a variable gain amplifier (VGA) 342 (which may include one or more stages) and a phase shifter 341. In an exemplary embodiment, the beamformer 349 may include a variable gain amplifier (VGA) (which may include one or more stages) 347 and a phase shifter 346.

In an exemplary embodiment, the phase shifter 341, VGA 342 and mixer 344 may be configured to operate on a transmit signal received from baseband circuitry (not shown); and the phase shifter 346, VGA 347 and mixer 348 may be configured to operate on a receive signal that is provided to the baseband circuitry. The baseband circuitry may be configured to operate at least partially at baseband, but may be configured to communicate with the circuitry 300 at other (e.g., intermediate) frequencies. In some examples, the circuitry 300 and baseband circuitry communicate with at least some signals that are at or near baseband.

In an exemplary embodiment, the frequency conversion components 340 may be connected to the band select switch 332, e.g., such that the frequency conversion components 340 are functionally coupled between the baseband circuitry and the band select switch 332. The band select switch 332 may be configured to route a signal to phased array elements (and associated antennas) configured for operation in different bands. In the illustrated example, the band select switch 332 is configured to toggle between phased array elements that support 21 and phased array elements that support 22, but the band select switch 332 may be omitted when only certain frequencies (e.g., one or several closely spaced bands) are supported and/or may be configured to select between additional bands when further bands are supported by the circuitry 300.

Frequency conversion components 350 may include an upconversion mixer 354, a beamformer 355, a downconversion mixer 358 and a beamformer 359. In an exemplary embodiment, the beamformer 355 may include a variable gain amplifier (VGA) 352 (which may include one or more stages) and a phase shifter 351. In an exemplary embodiment, the beamformer 359 may include a variable gain amplifier (VGA) (which may include one or more stages) 357 and a phase shifter 356.

In an exemplary embodiment, the phase shifter 351, VGA 352 and mixer 354 may be configured to operate on a transmit signal received from baseband circuitry (not shown); and the phase shifter 356, VGA 357 and mixer 358 may be configured to operate on a receive signal that is provided to the baseband circuitry (not shown).

In an exemplary embodiment, the frequency conversion components 350 may be connected to the band select switch 334, e.g., such that the frequency conversion components 350 are functionally coupled between the baseband circuitry and the band select switch 334. The band select switch 334 may be configured to route a signal to phased array elements (and associated antennas) configured for operation in different bands. In the illustrated example, the band select switch 334 is configured to toggle between phased array elements that support 21 and phased array elements that support 22, but the band select switch 334 may be omitted when only certain frequencies (e.g., one or several closely spaced bands) are supported and/or may be configured to select between additional bands when further bands are supported by the circuitry 300.

In some examples, the position of the band select switches 332, 334 are different than illustrated. For example, the band select switches 332, 334 may be implemented between a mixer (344, 348, 354, and/or 358) and the associated beamformer (345, 349, 355, and/or 359). In some examples, the band select switches are coupled between the baseband circuitry and several mixers, and respective mixers are used for λ1 and λ2. In still other examples, respective interfaces for λ1 and λ2 are implemented between the baseband circuitry and the circuitry 300 and the band select switches 332, 334 are omitted.

In some examples, several beamformers are coupled to a common mixer. For example, a common input to the circuitry 300 may be coupled to an input of the mixer 344 and the output of the mixer 344 may be coupled to inputs of both the beamformer 345 and the beamformer 355. In such an example, the mixer 354 may be omitted. Similarly, outputs of the beamformers 349 and 359 may be coupled to an input of the mixer 358, and an output of the mixer 358 may be coupled to a common output of the circuitry 300. In such an example, the mixer 348 may be omitted.

The example illustrated in FIG. 3 is configured to provide signal path phase shifting. In other embodiments, the phase shifters are instead coupled between an LO and the mixers and are configured to provide LO path phase shifting instead.

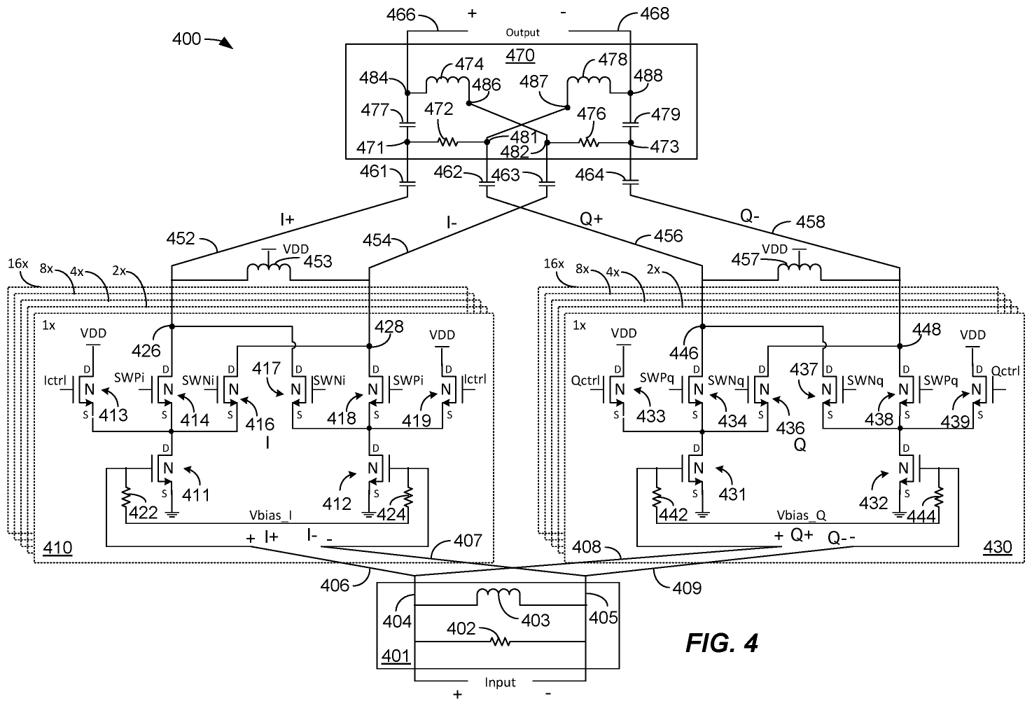

FIG. 4 is a schematic diagram 400 of a phase shifter of FIG. 3 (e.g., any of the signal path phase shifters 341, 346, 351, 356 or the non-illustrated LO path phase shifters). In an exemplary embodiment, the phase shifter circuit 400 comprises an input matching network 401, an in phase (I) VGA 410, a quadrature (Q) VGA 430 and a combining circuit 470. In an exemplary embodiment, the combining circuit 470 may be implemented as a quadrature all pass filter (QAF). While the VGA 410 is referred to as an in phase VGA and the VGA 430 is referred to as a quadrature VGA, no intentional (e.g., 90 degree) phase difference exists or is introduced between the signals in these components (although the polarity of the signals may be flipped or reversed in instances of the VGA 410 or 430). Rather, as described below, the I VGA and Q VGA are configured to receive the same differential signals from the matching network 401. The terms in phase and quadrature are used for convenience to describe circuitry that operate on signals which will eventually be processed to introduce a phase shift (e.g., in the combining circuit 470, which may be configured as a QAF), as described below. In an example, the I VGA 410 and Q VGA 430 may thus behave as a (active) vector modulator even though a (quadrature) phase difference does not exist between signals therein.

In an exemplary embodiment, the input matching network 401 may receive a differential input signal at connections 404 and 405. In some embodiments, a positive component (+ or p) of a differential signal may be provided on connection 404 and a negative component (−, or n) of a differential signal may be provided on connection 405. In other embodiments, a single-ended signal may be provided to the input matching network 401 and differential signals may be created using, for example, a balun (not shown). The signals on connections 404 and 405 may come from another amplifier stage, such as from a low noise amplifier LNA, or a stage of an LNA, such as one of the LNAs of FIG. 3, or from a VGA or stage of a VGA, such as one of the VGAs of FIG. 3. In an exemplary embodiment, the input matching network 401 may comprise passive components, such as for example only a resistance 402 and an inductance 403, which in the illustrated example are coupled in parallel between the connections 404 and 405. In other embodiments, the input matching network 401 may comprise other passive elements or passive elements arranged in a different configuration, and in some embodiments may comprise active elements.

In an exemplary embodiment, the positive input signal on connection 404 is provided via connections 406 and 408 to the VGAs 410 and 430, respectively; and the negative input signal on connection 405 is provided via connections 407 and 409 to the VGAs 410 and 430, respectively.

In an exemplary embodiment, the I VGA 410 includes transistors 411, 412, 413, 414, 416, 417, 418 and 419. In the example shown in FIG. 4, the transistors 411, 412, 413, 414, 416, 417, 418 and 419 are all N-type field effect transistors (N-FETs). However, the transistors 411, 412, 413, 414, 416, 417, 418 and 419 can alternatively be P-type FETs, or can be fabricated using other manufacturing technology and processes.

The drain of each of the transistors 413 and 419 is connected to a system voltage, VDD. The drain of the transistor 414 is connected to the drain of the transistor 417, both of which are connected to node 426 and the connection 452. The drain of the transistor 416 is connected to the drain of the transistor 418, both of which are connected to node 428 and the connection 454. Selectively enabling the transistors 414 and 418, or the transistors 416 and 417, may maintain or flip a polarity of the signals passing through the (instance of) the VGA 410.

The sources of the transistors 413, 414, and 416 are connected together and to the drain of the transistor 411. The sources of the transistors 417, 418, and 419 are connected together and to the drain of the transistor 412. The source of the transistor 411 and the source of the transistor 412 are connected to system ground. The transistors 411 and 412 may be configured as amplification transistors. The transistors 414, 416, 417, 418 may be configured in a cascode configuration and/or as switch transistors.

A gate of the transistor 411 is configured to receive the positive differential signal (I+) from connection 406 and a gate of the transistor 412 is configured to receive the negative differential signal (I−) from connection 407. The gate of the transistor 411 may be further connected to one side of a resistance 422 and a gate of the transistor 412 may be further connected to one side of a resistance 424. The other sides of the resistances 422 and 424 may be connected together and to a bias voltage, Vbias_I. The bias voltage Vbias_I may be provided by a bias circuit (not shown) to provide selected gain, noise figure and linearity performance.

A gate of the transistor 413 is configured to receive a control signal, Ictrl, and a gate of the transistor 419 is configured to receive the control signal, Ictrl. The control signal, Ictrl, may be provided by the data processor 210 (FIG. 2C) or by another controller.

A gate of the transistor 414 and a gate of the transistor 418 is configured to receive a signal, SWPi. A gate of the transistor 416 and a gate of the transistor 417 is configured to receive a signal, SWNi. The signals SWPi and SWNi may be provided by the data processor 210 (FIG. 2C) or by another controller. In an exemplary embodiment, the control signals SWPi and SWNi control the polarity of the RF signals processed by the corresponding transistors, and the control signal Ictrl controls whether a particular instance of the I VGA amplifies the input signal.

In an exemplary embodiment, an inductance 453 is located at an output of the I VGA 410 across the connections 452 and 454. The inductance 453 may be a center-tapped inductance with the center tap connected to a system voltage, VDD. These components may comprise a bias network. In other examples, other means for biasing the output of the VGA 410 (e.g., the drains of the transistors 414, 416, 417, 418 in the illustrated example) are implemented.

In an exemplary embodiment, the Q VGA 430 includes transistors 431, 432, 433, 434, 436, 437, 438 and 439. In the example shown in FIG. 4, the transistors 431, 432, 433, 434, 436, 437, 438 and 439 are all N-type field effect transistors (N-FETs). However, the transistors 431, 432, 433, 434, 436, 437, 438 and 439 can alternatively be P-type FETs, or can be fabricated using other manufacturing technology and processes.

The drain of each of the transistors 433 and 439 is connected to a system voltage, VDD. The drain of the transistor 434 is connected to the drain of the transistor 437, both of which are connected to node 446 and the connection 456. The drain of the transistor 436 is connected to the drain of the transistor 438, both of which are connected to node 448 and the connection 458. Selectively enabling the transistors 434 and 438, or the transistors 436 and 437, may maintain or flip a polarity of the signals passing through the (instance of) the VGA 430.

The sources of the transistors 433, 434, and 436 are connected together and to the drain of the transistor 431. The sources of the transistors 437, 438, and 439 are connected together and to the drain of the transistor 432. The source of the transistor 431 and the source of the transistor 432 are connected to system ground. The transistors 431 and 432 may be configured as amplification transistors. The transistors 434, 436, 437, 438 may be configured in a cascode configuration and/or as switch transistors.

A gate of the transistor 431 is configured to receive the positive differential signal (Q+) from connection 408 and a gate of the transistor 432 is configured to receive the negative differential signal (Q−) from connection 409. The gate of the transistor 431 may further be connected to one side of a resistance 442 and a gate of the transistor 432 may further be connected to one side of a resistance 444. The other sides of the resistances 442 and 444 may be connected together and to a bias voltage, Vbias_Q. The bias voltage Vbias_Q may be provided by a bias circuit (not shown) to provide selected gain, noise figure and linearity performance.

A gate of the transistor 433 is configured to receive a control signal, Qctrl, and a gate of the transistor 439 is configured to receive the control signal, Qctrl. The control signal, Qctrl, may be provided by the data processor 210 (FIG. 2C) or by another controller.

A gate of the transistor 434 and a gate of the transistor 438 is configured to receive a signal, SWPq. A gate of the transistor 436 and a gate of the transistor 437 is configured to receive a signal, SWNq. The signals SWNq and SWPq may be provided by the data processor 210 (FIG. 2C) or by another controller. In an exemplary embodiment, the control signals SWNq and SWPq control the polarity of the RF signals processed by the corresponding transistors, and the control signal Qctrl controls whether a particular instance of the corresponding Q VGA amplifies the input signal.

In an exemplary embodiment, an inductance 457 is located at an output of the Q VGA 430 across the connections 456 and 458. The inductance 457 may be a center-tapped inductance with the center tap connected to a system voltage, VDD. These components may comprise a bias network. In other examples, other means for biasing the output of the VGA 430 (e.g., the drains of the transistors 434, 436, 437, 438 in the illustrated example) are implemented.

To provide different amplification levels to the signals on connections 406, 407, 408 and 409, the I VGA 410 and the Q VGA 430 may be one instance of multiple instances of the I VGA and the Q VGA. For example, to provide different amplification levels, each instance of the I VGA and the Q VGA may be weighted. Example weighting may be binary weighting, thermometer coding, logarithmic weighting, etc. In an example binary weighting scheme with five (5) bit resolution, amplification levels can correspond to ×1, 2×, 4×, 8× and 16×, for example only. Providing different weights for each instance of the I VGA and the Q VGA can be implemented in various ways, for example, with transistors of different sizes across the multiple instances of the I VGA 410 and the Q VGA 430. To control how much amplification is provided, certain of the instances may be enabled or disabled, for example using the control signals Ictrl, Qctrl. The output of all instances of the I VGA may be coupled to the connections 452 and 454, and the inductor 453 (or other bias network). The output of all instances of the Q VGA may be coupled to the connections 456 and 458, and the inductor 457 (or other bias network).

The in phase positive differential signal, I+ is provided on connection 452, the in phase negative differential signal, I− is provided on connection 454, the quadrature positive differential signal, Q+ is provided on connection 456, and the quadrature negative differential signal, Q− is provided on connection 458. As described above, however, the I and Q nomenclature is used for ease of reference, and the I signals and Q signals are not provided in a quadrature phase shifted configuration by the VGAs. But the amplitude of the I signals and Q signals may have been adjusted by the VGAs such that an appropriately phase shifted signal is output by the combining circuit 470 based thereon.

In an exemplary embodiment the combining circuit 470 is a passive structure. The combining circuit 470 may be configured as a QAF which includes a resistance 472, a resistance 476, an inductance 474, an inductance 478, a capacitance 477, a capacitance 479.

The resistance is connected between a node 471 and a node 481. The resistance 476 is connected between a node 482 and a node 473. The inductance 474 is connected between a node 484 and a node 486. The inductance 478 is connected between a node 487 and a node 488. The capacitance 477 is connected between the node 471 and the node 484; and the capacitance 479 is connected between the node 488 and the node 473.

In an exemplary embodiment, the node 481 is connected to the node 487 and the node 482 is connected to the node 486. The node 484 is connected to a positive (+) output on connection 466 and the node 488 is connected to a negative (−) output on connection 468. Other configurations of a QAF may be implemented instead, for example in which the connections between the inductors 474 and 478, the capacitors 477 and 479, and the resistors 472 and 476 are different.

In an exemplary embodiment, the in phase positive signal on connection 452 is provided to a capacitance 461 and then to the node 471, and the in phase negative signal on connection 454 is provided to a capacitance 463 and then to the node 482.

In an exemplary embodiment, the quadrature positive signal on connection 456 is provided to a capacitance 462 and then to the node 481, and the quadrature negative signal on connection 458 is provided to a capacitance 464 and then to the node 473. In some examples, the capacitances 461-464 are DC blocking capacitors and/or all have approximately the same value.

In an exemplary embodiment, the I VGA 410 will selectively adjust an amplitude of the I+ and I− signals on connections 406 and 407 and provide the amplitude-adjusted I+ and I− signals on connections 452 and 454. In an exemplary embodiment, the Q VGA 430 will selectively adjust an amplitude of the Q+ and Q− signals on connections 408 and 409 and provide the amplitude-adjusted Q+ and Q− signals on connections 456 and 458.

In an exemplary embodiment, the phase shift for the (+) signal occurs at the output 466 of the combining circuit 470 where the I+ signal on connection 452 is combined with the Q+ signal on connection 456 and provided at the output of the combining circuit 470 on connection 466. The signal on connection 466 may be representative of a vector summation of the I+ signal on connection 452 and the Q+ signal on connection 456 (even though no quadrature phase difference exists at the output of the VGAs), as described below, with the resultant (+) signal on connection 466 being shifted in phase relative to the phase of the (+) signal on connection 404.

In an exemplary embodiment, the phase shift for the (−) signal occurs at the output 468 of the combining circuit 470 where the I− signal on connection 454 is combined with the Q− signal on connection 458 and provided at the output of the QAF 470 on connection 468. The signal on connection 468 may be representative of a vector summation of the I− signal on connection 454 and the Q− signal on connection 458 (even though no quadrature phase difference exists at the output of the VGAs), as described below, with the resultant (−) signal on connection 468 being shifted in phase relative to the phase of the (−) signal on connection 405. A differential implementation is presented herein, but a single-ended implementation may be utilized instead.

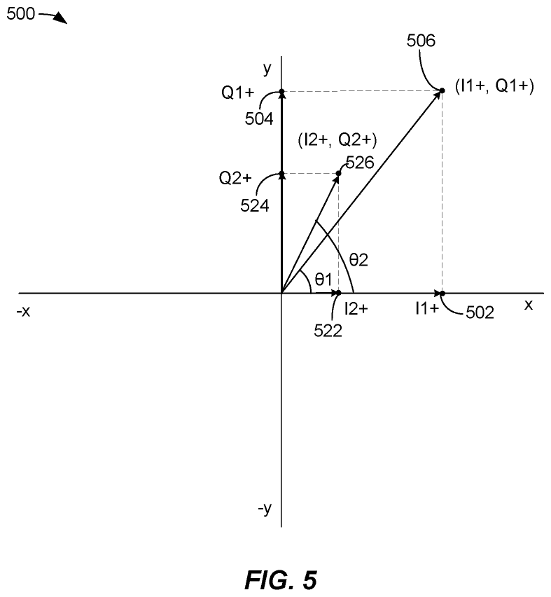

FIG. 5 is a graphical illustration of the operation of the phase shifter circuit 400 of FIG. 4. In an exemplary embodiment, a graph 500 shows a plot including an in phase horizontal axis (x, −x) and a quadrature vertical axis (y, −y).

Referring to FIG. 4 as an example only, an I1+ signal on connection 452 is represented by the point 502 and a Q1+ signal on connection 456 is represented by the point 504. While the output of the VGAs 410, 430 do not have a quadrature phase difference, as represented in the graph 500, the combination of the I+ and Q+ signal by the combining circuit 470 (e.g., the output of the combining circuit 470) can be represented by a vector having an end at the point 506. This vector has a first phase (θ1) generated by the phase shifter circuit 400 based on the amplitudes of the signals on connections 452 and 456. Similarly, the combining circuit 470 may combine an I− signal on connection 454 and a Q− signal on connection 458 to generate a negative output signal having the first phase (θ1).

In an exemplary embodiment, the phase shifter circuit 400 can generate another phase signal, whereby an I2+ signal on connection 452 is represented by the point 522 and a Q2+ signal on connection 456 is represented by the point 524. The combination of these signals by the combining circuit 470 (e.g., the output of the combining circuit 470) can be represented by a vector having an end at the point 526. This vector has a second phase (θ2) generated by the phase shifter circuit 400 based on the amplitudes of the signals on connections 452 and 456. The second phase (θ2) can be different than the first phase (θ2). In an exemplary embodiment, multiple instances of the phase shifter circuit 400 may be implemented in a transceiver having the circuitry 300 (FIG. 3), for example to generate beamformed signals. In an example, the phase shifter circuit 400 is implemented in each of a plurality of phased array elements 287, and the phase of signals output from these phased array elements 287 is set as described above to form a desired transmit or receive beam. For example, a first phased array element 287 may output a signal having the phase θ1 and a second phased array element 287 may output a signal having the phase θ2.

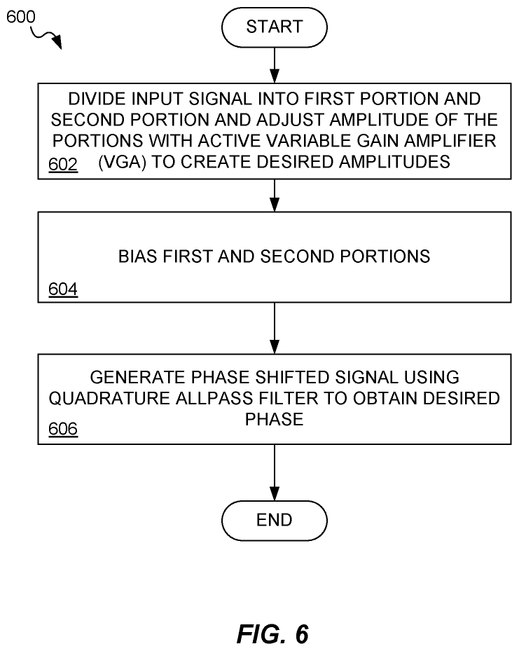

FIG. 6 is a flow chart 600 describing an example of the operation of a method for phase shifting. The blocks in the method 600 can be performed in or out of the order shown, and in some embodiments, can be performed at least in part in parallel.

In block 602, an input signal is split into a first portion and a second portion, and amplitudes of the two portions are adjusted using active variable gain amplifiers (VGAs) to create desired amplitudes. For example, the I VGA 410 and the Q VGA 430 may adjust the amplitudes of signals from connections 406 and 408 that were split from an input signal on connection 404 to create desired amplitudes.

In block 604, the amplified first and second portions are biased. For example, the center tapped inductors 453 and 457 may bias the outputs of the I VGA 410 and the Q VGA 430.

In block 606, a phase shifted signal is generated based on the biased amplified first and second portions using a quadrature all pass filter to obtain a desired phase shift (e.g., as compared to the input signal and/or as compared to signals output from another phase shifter in the system). For example, the QAF 470 may receive the input signals from the I VGA 410 and the Q VGA 430 and generate an output signal on connection 466 that has a desired phase shift, for example as compared to the signal on connection 404.

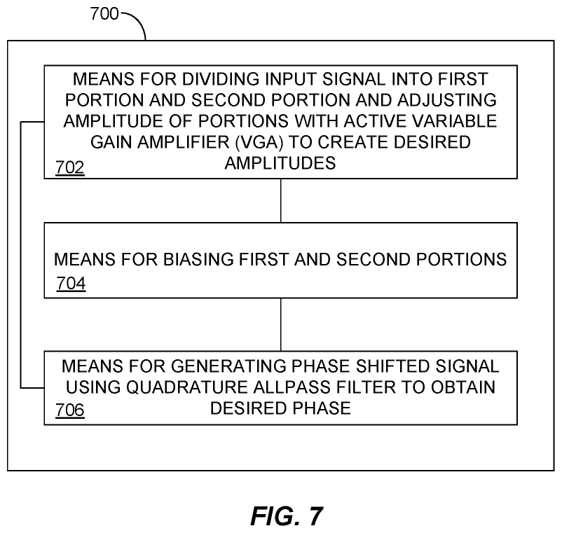

FIG. 7 is a functional block diagram of an apparatus 700 for phase shifting processing. The apparatus 700 comprises means 702 for splitting an input signal into a first portion and a second portion and adjusting an amplitude of the two portions using a variable gain amplifier (VGA) to create desired amplitudes. In certain embodiments, the means 702 for splitting an input signal into a first portion and a second portion and adjusting an amplitude of the two portions using a variable gain amplifier (VGA) to create desired amplitudes can be configured to perform one or more of the functions described in operation block 602 of method 600 (FIG. 6). In an exemplary embodiment, the means 702 for splitting an input signal into a first portion and a second portion and adjusting an amplitude of the two portions using a variable gain amplifier (VGA) to create desired amplitudes may comprise the input matching network 401 configured to split the signal on connection 404 so that the I VGA 410 and the Q VGA 430 may amplify an input signal to create desired amplitudes.

The apparatus 700 may also comprise means 704 for biasing the amplified first and second portions. In certain embodiments, the means 704 for biasing the amplified first and second portions can be configured to perform one or more of the functions described in operation block 604 of method 600 (FIG. 6). In an exemplary embodiment, the means 704 for biasing the amplified first and second portions may comprise the center tapped inductors 453 and 457 configured to bias the outputs of the I VGA 410 and the Q VGA 430.

The apparatus 700 may also comprise means 706 for generating a phase shifted signal based on the biased amplified first and second portions using a quadrature all pass filter to obtain a desired phase. In certain embodiments, the means 706 for generating a phase shifted signal based on the biased amplified first and second portions using a quadrature all pass filter to obtain a desired phase can be configured to perform one or more of the functions described in operation block 606 of method 600 (FIG. 6). In an exemplary embodiment, the means 706 for generating a phase shifted signal based on the biased amplified first and second portions using a quadrature all pass filter to obtain a desired phase may comprise the QAF 470 configured to receive the input signals from the I VGA 410 and the Q VGA 430 and generate an output signal on connection 466 that has a desired phase shift (e.g., as compared to the signal on connection 404 or as compared to a signal output from another phase shifter or apparatus for phase shift processing).

Certain example phase shifters described above may reduce power and/or area as compared to previous phase shifters. For example, described phase shifters may be smaller and consume less power consume, but provide similar performance. Example phase shifters may also exhibit less loss, provide higher resolution, and/or provide wideband performance. In some transceiver designs, a phase shifter configured as described above may be used to set a phase of transmit signals and another phase shifter configured as described above may be used to set a phase of receive signals. In some such designs, having similar phase shifters for transmit and receive may simplify design and/or increase the ability to optimize performance. For example, receive phase shifters can be optimized for small area and/or good noise figure. As another example, transmit phase shifters can be optimized for good linearity.

A QAF as included in certain example phase shifters described above may be wideband and/or not sensitive to a Q of an inductor or capacitor therein, and potentially efficient in terms of area. When used in a receive chain the QAF at the output of the phase shifter may allow the noise in the passive network to divide to the amplifier gain, thereby lowering NF.

Certain example configurations described above can be used in a 3 bit or a 5 bit phase shifter.

Implementation examples are described in the following numbered clauses:

1. A phase shifter, comprising: an input matching network; a vector modulator connected to the input matching network, the vector modulator configured to alter an amplitude of signals provided by the input matching network; bias networks coupled to outputs of the vector modulator; and a combining circuit connected to the outputs of the vector modulator, the combining circuit configured to generate a first phase (θ1) signal from the outputs of the vector modulator.

2. The phase shifter of clause 1, wherein the vector modulator is an active device.

3. The phase shifter of any of clauses 1 or 2, wherein the combining circuit is a quadrature all pass filter (QAF).

4. The phase shifter of clause 3, wherein the QAF is a passive device.

5. The phase shifter of any of clauses 2 through 4, wherein the vector modulator comprises an in phase variable gain amplifier and a quadrature variable gain amplifier.

6. The phase shifter of any of clauses 2 through 5, wherein the vector modulator provides an in phase positive differential signal (I+), an in phase negative differential signal (I−), a quadrature positive differential signal (Q+), and a quadrature negative differential signal (Q−), where the in phase positive differential signal (I+), the quadrature positive differential signal (Q+), the in phase negative differential signal (I−) and the quadrature negative differential signal (Q−) are combined to generate a signal having the first phase (θ1) determined by selective amplification provided by the vector modulator.

7. The phase shifter of any of clauses 2 through 6, wherein the first phase (θ1) can be changed to a second phase (θ2) by adjusting the amplification provided by the vector modulator.

8. The phase shifter of clause 7, wherein (θ1) is different than (θ2).

9. The phase shifter of any of clauses 3 through 6, wherein the combining circuit is configured to combine the in phase positive differential signal (1+) and the quadrature positive differential signal (Q+) to generate a positive output signal having the first phase (θ1).

10. The phase shifter of any of clauses 3 through 6, wherein the combining circuit is configured to combine the in phase negative differential signal (I−) and the quadrature negative differential signal (Q−) to generate a negative output signal having the first phase (θ1).

11. The phase shifter of any of clauses 5 through 10, wherein the in phase variable gain amplifier and the quadrature variable gain amplifier each comprise multiple instances configured to provide different amplification levels.

12. The phase shifter of any of clauses 1 through 12, wherein the bias networks comprise a system voltage supply connected to a center tap of an inductive element.

13. A method for phase shifting, comprising: dividing an input signal into a first portion and a second portion and adjusting an amplitude of the first and second portions; biasing the amplitude-adjusted first portion and the amplitude-adjusted second portion; and passively combining the amplitude-adjusted first and second portions to generate a first phase (θ1) signal.

14. The method of clause 13, wherein adjusting an amplitude of the first and second portions comprises actively adjusting an amplitude of the first and second portions using active variable gain amplifiers (VGAs).

15. The method of clause 14, wherein the actively adjusting further comprises selectively amplifying an in phase positive differential signal (I+), an in phase negative differential signal (I−), a quadrature positive differential signal (Q+), and a quadrature negative differential signal (Q−).

16. The method of any of clauses 13 through 15, wherein the passively combining is performed by a passive quadrature all pass filter (QAF).

17. The method of any of clauses 13 through 16, further comprising passively combining the in phase positive differential signal (I+) and the quadrature positive differential signal (Q+) to generate a positive output signal having the first phase (θ1).

18. The method of any of clauses 13 through 16, further comprising passively combining the in phase negative differential signal (I−) and the quadrature negative differential signal (Q−) to generate a negative output signal having the first phase (θ1).

19. The method of any of clauses 13 through 18, wherein the biasing further comprises biasing the amplitude-adjusted first portion and the amplitude-adjusted second portion using a system voltage supply connected to a center tap of an inductive element.

20. A device, comprising: means for dividing an input signal into a first portion and a second portion and actively adjusting an amplitude of the first and second portions; means for biasing the amplitude-adjusted first portion and the amplitude-adjusted second portion; and means for passively combining the amplitude-adjusted first portion and the amplitude-adjusted second portion using a passive combiner to generate a first phase (θ1) signal.

21. The device of clause 20, wherein the means for actively adjusting further comprises means for selectively amplifying an in phase positive differential signal (I+), an in phase negative differential signal (I−), a quadrature positive differential signal (Q+), and a quadrature negative differential signal (Q−).

22. The device of any of clauses 20 or 21, wherein the means for passively combining comprises means for passively combining the in phase positive differential signal (I+) and the quadrature positive differential signal (Q+) to generate a positive output signal having the first phase (θ1).

23. The device of any of clauses 20 through 21, wherein the means for passively combining comprises means for passively combining the in phase negative differential signal (I−) and the quadrature negative differential signal (Q−) to generate a negative output signal having the first phase (θ1).

24. A phase shifter, comprising: an input matching network coupled to an input of the phase shifter; a variable gain amplifier, wherein an output of the input matching network is coupled to a gate of an amplification transistor in the variable gain amplifier; and a quadrature all pass filter (QAF) coupled to an output of the variable gain amplifier and to an output of the phase shifter.

25. The phase shifter of clause 24, wherein the QAF is coupled to drains of transistors in the variable gain amplifier having a cascode or switch transistor configuration.

26. The phase shifter of any of clauses 24 or 25, comprising a plurality of variable gain amplifiers, the plurality of variable gain amplifiers coupled to the output of the input matching network, each of the plurality of variable gain amplifiers comprising an output coupled to the QAF.

27. The phase shifter of clause 26, further comprising a plurality of capacitors coupled between respective outputs of the plurality of variable gain amplifiers and the QAF, the plurality of capacitors having approximately the same value.

28. The phase shifter of clause 24, wherein the variable gain amplifier comprises a second transistor having a drain, gate, and source, the source of the second transistor coupled to a drain of the amplification transistor, the drain of the second transistor coupled to a supply voltage, and the gate of the second transistor coupled to a control signal.

29. The phase shifter of clause 28, further comprising a center-tapped inductor coupled to the output of the variable gain amplifier.

30. The phase shifter of any of clauses 24 through 29, wherein the phase shifter is included in a phased array element of a phased array configured to operate with a frequency in the range of 7-24 GHz.

The circuit architecture described herein described herein may be implemented on one or more ICs, analog ICs, RFICs, mixed-signal ICs, ASICs, printed circuit boards (PCBs), electronic devices, etc. The circuit architecture described herein may also be fabricated with various IC process technologies such as complementary metal oxide semiconductor (CMOS), N-channel MOS (NMOS), P-channel MOS (PMOS), bipolar junction transistor (BJT), bipolar-CMOS (BiCMOS), silicon germanium (SiGe), gallium arsenide (GaAs), heterojunction bipolar transistors (HBTs), high electron mobility transistors (HEMTs), silicon-on-insulator (SOI), etc.

An apparatus implementing the circuit described herein may be a stand-alone device or may be part of a larger device. A device may be (i) a stand-alone IC, (ii) a set of one or more ICs that may include memory ICs for storing data and/or instructions, (iii) an RFIC such as an RF receiver (RFR) or an RF transmitter/receiver (RTR), (iv) an ASIC such as a mobile station modem (MSM), (v) a module that may be embedded within other devices, (vi) a receiver, cellular phone, wireless device, handset, or mobile unit, (vii) etc.

Although selected aspects have been illustrated and described in detail, it will be understood that various substitutions and alterations may be made therein without departing from the spirit and scope of the present invention, as defined by the following claims.

What is claimed is:

1. A phase shifter, comprising:
an input matching network;
a vector modulator connected to the input matching network, the vector modulator configured to alter an amplitude of signals provided by the input matching network;
bias networks coupled to outputs of the vector modulator; and
a combining circuit connected to the outputs of the vector modulator, the combining circuit configured to generate a first phase (θ1) signal from the outputs of the vector modulator.

2. The phase shifter of claim 1, wherein the vector modulator is an active device.

3. The phase shifter of claim 1, wherein the combining circuit is a quadrature all pass filter (QAF).

4. The phase shifter of claim 3, wherein the QAF is a passive device.

5. The phase shifter of claim 4, wherein the vector modulator comprises an in phase variable gain amplifier and a quadrature variable gain amplifier.

6. The phase shifter of claim 1, wherein the vector modulator provides an in phase positive differential signal (I+), an in phase negative differential signal (I−), a quadrature positive differential signal (Q+), and a quadrature negative differential signal (Q−), where the in phase positive differential signal (I+), the quadrature positive differential signal (Q+), the in phase negative differential signal (I−) and the quadrature negative differential signal (Q−) are combined to generate a signal having the first phase (θ1) determined by selective amplification provided by the vector modulator.

7. The phase shifter of claim 6, wherein the first phase (θ1) can be changed to a second phase (θ2) by adjusting the amplification provided by the vector modulator.

8. The phase shifter of claim 7, wherein (θ1) is different than (θ2).

9. The phase shifter of claim 6, wherein the combining circuit is configured to combine the in phase positive differential signal (I+) and the quadrature positive differential signal (Q+) to generate a positive output signal having the first phase (θ1).

10. The phase shifter of claim 6, wherein the combining circuit is configured to combine the in phase negative differential signal (I−) and the quadrature negative differential signal (Q−) to generate a negative output signal having the first phase (θ1).

11. The phase shifter of claim 5, wherein the in phase variable gain amplifier and the quadrature variable gain amplifier each comprise multiple instances configured to provide different amplification levels.

12. The phase shifter of claim 1, wherein the bias networks comprise a system voltage supply connected to a center tap of an inductive element.

13. A method for phase shifting, comprising:
dividing an input signal into a first portion and a second portion and adjusting an amplitude of the first and second portions;
biasing the amplitude-adjusted first portion and the amplitude-adjusted second portion; and
passively combining the amplitude-adjusted first and second portions to generate a first phase (θ1) signal.

14. The method of claim 13, wherein adjusting an amplitude of the first and second portions comprises actively adjusting an amplitude of the first and second portions using active variable gain amplifiers (VGAs).

15. The method of claim 14, wherein the actively adjusting further comprises selectively amplifying an in phase positive differential signal (I+), an in phase negative differential signal (I−), a quadrature positive differential signal (Q+), and a quadrature negative differential signal (Q−).

16. The method of claim 15, wherein the passively combining is performed by a passive quadrature all pass filter (QAF).

17. The method of claim 16, further comprising passively combining the in phase positive differential signal (I+) and the quadrature positive differential signal (Q+) to generate a positive output signal having the first phase (θ1).

18. The method of claim 16, further comprising passively combining the in phase negative differential signal (I−) and the quadrature negative differential signal (Q−) to generate a negative output signal having the first phase (θ1).

19. The method of claim 13, wherein the biasing further comprises biasing the amplitude-adjusted first portion and the amplitude-adjusted second portion using a system voltage supply connected to a center tap of an inductive element.

20. A device, comprising:
means for dividing an input signal into a first portion and a second portion and actively adjusting an amplitude of the first and second portions;
means for biasing the amplitude-adjusted first portion and the amplitude-adjusted second portion; and
means for passively combining the amplitude-adjusted first portion and the amplitude-adjusted second portion using a passive combiner to generate a first phase (θ1) signal.

21. The device of claim 20, wherein the means for actively adjusting further comprises means for selectively amplifying an in phase positive differential signal (I+), an in phase negative differential signal (I−), a quadrature positive differential signal (Q+), and a quadrature negative differential signal (Q−).

22. The device of claim 21, wherein the means for passively combining comprises means for passively combining the in phase positive differential signal (I+) and the quadrature positive differential signal (Q+) to generate a positive output signal having the first phase (θ1).

23. The device of claim 21, wherein the means for passively combining comprises means for passively combining the in phase negative differential signal (I−) and the quadrature negative differential signal (Q−) to generate a negative output signal having the first phase (θ1).

24. A phase shifter, comprising:
an input matching network coupled to an input of the phase shifter;
a variable gain amplifier, wherein an output of the input matching network is coupled to a gate of an amplification transistor in the variable gain amplifier; and
a quadrature all pass filter (QAF) coupled to an output of the variable gain amplifier and to an output of the phase shifter.

25. The phase shifter of claim 24, wherein the QAF is coupled to drains of transistors in the variable gain amplifier having a cascode or switch transistor configuration.

26. The phase shifter of claim 24, comprising a plurality of variable gain amplifiers, the plurality of variable gain amplifiers coupled to the output of the input matching network, each of the plurality of variable gain amplifiers comprising an output coupled to the QAF.

27. The phase shifter of claim 26, further comprising a plurality of capacitors coupled between respective outputs of the plurality of variable gain amplifiers and the QAF, the plurality of capacitors having approximately the same value.

28. The phase shifter of claim 24, wherein the variable gain amplifier comprises a second transistor having a drain, gate, and source, the source of the second transistor coupled to a drain of the amplification transistor, the drain of the second transistor coupled to a supply voltage, and the gate of the second transistor coupled to a control signal.

29. The phase shifter of claim 28, further comprising a center-tapped inductor coupled to the output of the variable gain amplifier.

30. The phase shifter of claim 24, wherein the phase shifter is included in a phased array element of a phased array configured to operate with a frequency in the range of 7-24 GHz.
